(19) United States
(12) Patent Application Publication
(10) Pub. No.: US 2018/0167095 A1
(43) Pub. Date: Jun. 14, 2018

(54) COMPACT 3D RECEIVER ARCHITECTURE USING SILICON GERMANIUM THRU SILICON VIA TECHNOLOGY

(71) Applicant: GM GLOBAL TECHNOLOGY OPERATIONS LLC, Detroit, MI (US)

(72) Inventors: Cynthia D. BARINGER, Piedmont, CA (US); Mohiuddin AHMED, Moorpark, CA (US); Jongchan KANG, Moorpark, CA (US); Yen-Cheng KUAN, Los Angeles, CA (US); James Chingwei LI, Simi Valley, CA (US); Emilio A. SOVERO, Thousands Oaks, CA (US); Timothy J. TALTY, Beverly Hills, MI (US)

(21) Appl. No.: 15/378,706

(22) Filed: Dec. 14, 2016

(51) Int. Cl. H04B 1/16; H01L 23/48; H01L 27/06; H01L 23/66

(52) U.S. Cl. CPC H04B 1/16; H01L 23/481; H01L 29/737; H01L 23/66; H01L 2223/6677; H01L 27/0694

(57) ABSTRACT

A wide bandwidth radio system designed to adapt to various global radio standards and, more particularly, to a system and method incorporate a compact receiver array design to support the demand for increased mobile broadband services using a through-silicon vias to interconnect front-end analog functions in SiGe BiCMOS to backend circuitry in CMOS.

### BACKGROUND

### Field of the Technology

The present application generally relates to wide bandwidth radio system designed to adapt to various global radio standards and, more particularly, to a cellular radio architecture that employs a combination of a single circulator, programmable band-pass sampling radio frequency (RF) front-end and optimized digital baseband that is capable of supporting all current cellular wireless access protocol frequency bands. The system and method incorporate a compact receiver array design to support the demand for increased mobile broadband services using a through-silicon vias (TSVs) to interconnect front-end analog functions in SiGe BiCMOS to backend circuitry in CMOS.

### Discussion of the Related Art

Traditional cellular telephones employ different modes and bands of operation that have been supported in hardware by having multiple disparate radio front-end and baseband processing chips integrated into one platform, such as tri-band or quad-band user handsets supporting global system for mobile communications (GSM), general packet radio service (GPRS), etc. Known cellular receivers have integrated some of the antenna and baseband data paths, but nevertheless the current state of the art for mass mobile and vehicular radio deployment remains a multiple static channelizing approach. Such a static architecture is critically dependent on narrow-band filters, duplexers and standard-specific down-conversion to intermediate-frequency (IF) stages. The main disadvantage of this static, channelized approach is its inflexibility with regards to the changing standards and modes of operation. As the cellular communications industry has evolved from 2G, 3G, 4G and beyond, each new waveform and mode has required a redesign of the RF front-end of the receiver as well as expanding the baseband chip set capability, thus necessitating a new handset. For automotive applications, this inflexibility to support emerging uses is prohibitively expensive and a nuisance to the end-user.

Providing reliable automotive wireless access is challenging from an automobile manufacturers point of view because cellular connectivity methods and architectures vary across the globe. Further, the standards and technologies are ever changing and typically have an evolution cycle that is several times faster than the average service life of a vehicle. More particularly, current RF front-end architectures for vehicle radios are designed for specific RF frequency bands. Dedicated hardware tuned at the proper frequency needs to be installed on the radio platform for the particular frequency band that the radio is intended to operate at. Thus, if cellular providers change their particular frequency band, the particular vehicle that the previous band was tuned for, which may have a life of 15 to 20 years, may not operate efficiently at the new band. Hence, this requires automobile manufactures to maintain a mvriad of radio platforms, components and suppliers to support each deployed standard, and to provide a path to upgradability as the cellular landscape changes, which is an expensive and complex proposition.

Known software-defined radio architectures have typically focused on seamless baseband operations to support multiple waveforms and have assumed similar down-conversion-to-baseband specifications. Similarly, for the transmitter side, parallel power amplifier chains for different frequency bands have typically been used for supporting different waveform standards. Thus, receiver front-end architectures have typically been straight forward direct sampling or one-stage mixing methods with modest performance specifications. In particular, no prior application has required a greater than 110 dB dynamic range with associated IP3 factor and power handling requirements precisely because such performance needs have not been realizable with complementary metal oxide semiconductor (CMOS) analog technologies. It has not been obvious how to achieve these metrics using existing architectures for CMOS devices, thus the dynamic range, sensitivity and multi-mode interleaving for both the multi-bit analog-to-digital converter (ADC) and the digital-to-analog converter (DAC) is a substantially more difficult problem.

Delta-sigma modulators are becoming more prevalent in digital receivers because, in addition to providing wideband high dynamic range operation, the modulators have many tunable parameters making them a good candidate for reconfigurable systems. In particular, delta-sigma modulators include a software tunable filter for noise shaping an incoming RF signal. It would be desirable be able to take advantage of the various advantages of both SiGe BiCMOS and CMOS simultaneously is a software controlled radio with delta sigma modulators.

### SUMMARY OF THE INVENTION

The present disclosure describes an apparatus comprising a first semiconductor layer formed of silicon germanium, a second semiconductor layer formed of silicon, a first device formed on the first semiconductor layer, a second device formed on the second semiconductor layer, and a through silicon via coupling the first device and the second device wherein the through silicon via passes through the first semiconductor layer and the second semiconductor layer.

Another aspect of the present disclosure describes a software programmable radio comprising a delta sigma modulator formed on a SiGe layer of an integrated circuit, a digital signal processor formed on a silicon layer of the integrated circuit, a through via coupling the delta sigma modulator to the digital signal processor wherein the through via passes through the SiGe layer of the integrated circuit and the silicon layer of the integrated circuit.

Another aspect of the present disclosure describes integrated circuit comprising a first semiconductor layer formed of silicon germanium, a second semiconductor layer formed of silicon, a first device formed on the first semiconductor layer, a second device formed on the second semiconductor layer, and a through silicon via coupling the first device and the second device wherein the trough silicon via passes through the first semiconductor layer and the second semiconductor layer.

Additional features of the present invention will become apparent from the following description and appended claims, taken in conjunction with the accompanying drawings.

### BRIEF DESCRIPTION OF THE DRAWINGS

FIG. 1 shows a block diagram of a known multi-mode, multi-band cellular communications handset architecture:

FIG. 2 shows a block diagram of a software-programmable cellular radio architecture applicable;

FIG. 3 shows an exemplary radio architecture to implement a delta-sigma modulator in a software defined programmable cellular radio.

FIG. 4 shows an exemplary cross section of an apparatus having a SiGe BiCMOS and CMOS chip stacks coupled via TSVs.

### DETAILED DESCRIPTION OF THE EMBODIMENTS

The following discussion of the embodiments of the invention directed to a cellular radio architecture is merely exemplary in nature, and is in no way intended to limit the invention or its applications or uses. For example, the radio architecture of the invention is described as having application for a vehicle. However, as will be appreciated by those skilled in the art, the radio architecture may have applications other than automotive applications.

The cellular radio architectures discussed herein are applicable to more than cellular wireless technologies, for example, WiFi (IEEE 802.11) technologies. Further, the cellular radio architectures are presented as a fully duplexed wireless system, i.e., one that both transmits and receives. For wireless services that are receive only, such as global positioning system (GPS), global navigation satellite system (GNSS) and various entertainment radios, such as AM/FM, digital audio broadcasting (DAB), SiriusXM, etc., only the receiver design discussed herein would be required. Also, the described radio architecture design will enable one radio hardware design to function globally, accommodating various global wireless standards through software updates. It will also enable longer useful lifespan of the radio hardware design by enabling the radio to adapt to new wireless standards when they are deployed in the market. For example, 4G radio technology developments and frequency assignments are very dynamic. Thus, radio hardware deployed in the market may become obsolete after just one or two years. For applications, such as in the automotive domain, the lifespan can exceed ten years. This invention enables a fixed hardware platform to be updateable through software updates, thus extending the useful lifespan and global reuse of the hardware.

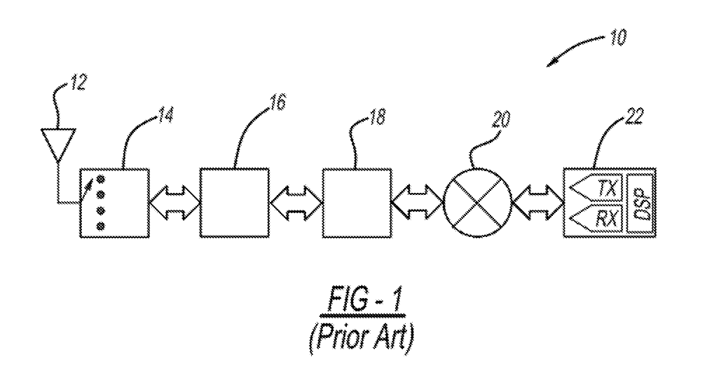

FIG. 1 is a block diagram of a known multi-mode, multi-band cellular communications user handset architecture 10 for a typical cellular telephone. The architecture 10 includes an antenna structure 12 that receives and transmits RF signals at the frequency band of interest. The architecture 10 also includes a switch 14 at the very front-end of the architecture 10 that selects which particular channel the transmitted or received signal is currently for and directs the signal through a dedicated set of filters and duplexers represented by box 16 for the particular channel. Modules 18 provide multi-mode and multi-band analog modulation and demodulation of the receive and transmit signals and separates the signals into in-phase and quadrature-phase signals sent to or received from a transceiver 20. The transceiver 20 also converts analog receive signals to digital signals and digital transmit signals to analog signals. A baseband digital signal processor 22 provides the digital processing for the transmit or receive signals for the particular application.

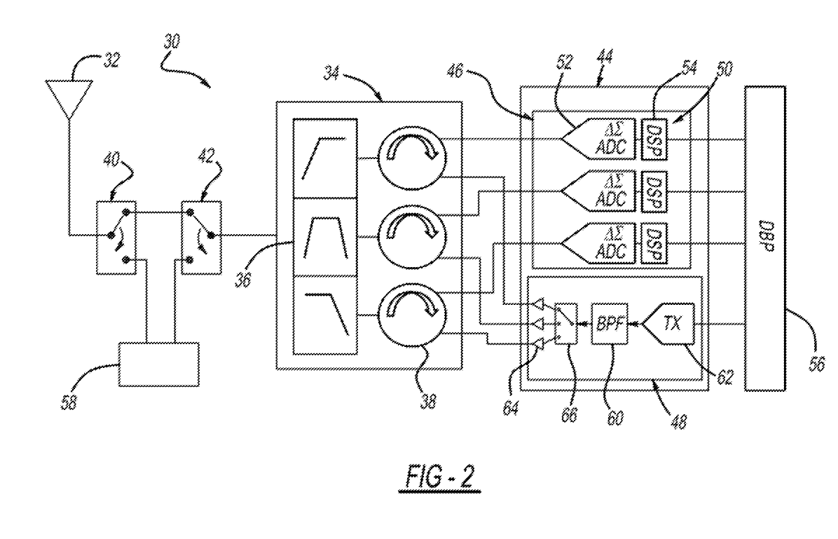

FIG. 2 is a schematic block diagram of a cellular radio front-end architecture 30 that provides software programmable capabilities as will be discussed in detail below. The architecture 30 includes an antenna structure 32 capable of receiving and transmitting the cellular frequency signals discussed herein, such as in a range of 400 MHz-3.6 GHz. Signals received and transmitted by the antenna structure 32 go through a multiplexer 34 that includes three signal paths, where each path is designed for a particular frequency band as determined by a frequency selective filter 36 in each path. In this embodiment, three signal paths have been selected, however, the architecture 30 could be expanded to any number of signal paths. Each signal path includes a circulator 38 that separates and directs the receive and transmit signals, and provides isolation so that the high power signals being transmitted do not enter the receiver side and saturate the receive signals at those frequency bands.

The architecture 30 also includes a front-end transceiver module 44 that is behind the multiplexer 34 and includes a receiver module 46 that processes the receive signals and a transmitter module 48 that processes the transmit signals. The receiver module 46 includes three receiver channels 50, one for each of the signal paths through the multiplexer 34, where a different one of the receiver channels 50 is connected to a different one of the circulators 38, as shown. Each of the receiver channels 50 includes a delta-sigma modulator 52 that receives the analog signal at the particular frequency band and generates a representative stream of digital data using an interleaving process in connection with a number of N-bit quantizer circuits operating at a very high clock rate, as will be discussed in detail below. As will further be discussed, the delta-sigma modulator 52 compares the difference between the receive signal and a feedback signal to generate an error signal that is representative of the digital data being received. The digital data bits are provided to a digital signal processor (DSP) 54 that extracts the digital data stream. A digital baseband processor (DBP) 56 receives and operates on the digital data stream for further signal processing in a manner well understood by those skilled in the art. The transmitter module 48 receives digital data to be transmitted from the processor 56. The module 48 includes a transmitter circuit 62 having a delta-sigma modulator that converts the digital data from the digital baseband processor 56 to an analog signal. The analog signal is filtered by a tunable bandpass filter (BPF) 60 to remove out of band emissions and sent to a switch 66 that directs the signal to a selected power amplifier 64 optimized for the transmitted signal frequency band. In this embodiment, three signal paths have been selected, however, the transmitter module 48 could be implemented using any number of signal paths. The amplified signal is sent to the particular circulator 38 in the multiplexer 34 depending on which frequency is being transmitted.

As will become apparent from the discussion below, the configuration of the architecture 30 provides software programmable capabilities through high performance delta-sigma modulators that provide optimized performance in the signal band of interest and that can be tuned across a broad range of carrier frequencies. The architecture 30 meets current cellular wireless access protocols across the 0.4-2.6 GHz frequency range by dividing the frequency range into three non-continuous bands. However, it is noted that other combinations of signal paths and bandwidth are of course possible. The multiplexer 34 implements frequency domain de-multiplexing by passing the RF carrier received at the antenna structure 32 into one of the three signal paths. Conversely, the transmit signal is multiplexed through the multiplexer 34 onto the antenna structure 32. For vehicular wireless access applications, such a low-cost integrated device is desirable to reduce parts cost, complexity, obsolescence and enable seamless deployment across the globe.

The delta-sigma modulators 52 may be positioned near the antenna structure 32 so as to directly convert the RF receive signals to bits in the receiver module 46 and bits to an RF signal in the transmitter module 48. The main benefit of using the delta-sigma modulators 52 in the receiver channels 50 is to allow a variable signal capture bandwidth and variable center frequency. This is possible because the architecture 30 enables software manipulation of the modulator filter coefficients to vary the signal bandwidth and tune the filter characteristics across the RF band, as will be discussed below.

The architecture 30 allows the ability to vary signal capture bandwidth, which can be exploited to enable the reception of continuous carrier aggregated waveforms without the need for additional hardware. Carrier aggregation is a technique by which the data bandwidths associated with multiple carriers for normally independent channels are combined for a single user to provide much greater data rates than a single carrier. Together with MIMO, this feature is a requirement in modem 4G standards and is enabled by the orthogonal frequency division multiplexing (OFDM) family of waveforms that allow efficient spectral usage.

The architecture 30 through the delta-sigma modulators 52 can handle the situation for precise carrier aggregation scenarios and band combinations through software tuning of the bandpass bandwidth, and thus enables a multi-segment capture capability. Dynamic range decreases for wider bandwidths where more noise is admitted into the sampling bandpass. However, it is assumed that the carrier aggregation typically makes sense when the user has a good signal-to-noise ratio, and not cell boundary edges when connectivity itself may be marginal. Note that the inter-band carrier aggregation is automatically handled by the architecture 30 since the multiplexer 34 feeds independent modulators in the channels 50.

The circulators 38 route the transmit signals from the transmitter module 48 to the antenna structure 32 and also provide isolation between the high power transmit signals and the receiver module 46. Although the circulators 38 provide significant signal isolation, there is some port-to-port leakage within the circulator 38 that provides a signal path between the transmitter module 48 and the receiver module 46. A second undesired signal path occurs due to reflections from the antenna structure 32, and possible other components in the transceiver. As a result, a portion of the transmit signal will be reflected from the antenna structure 32 due to a mismatch between the transmission line impedance and the antenna's input impedance. This reflected energy follows the same signal path as the incoming desired signal back to the receiver module 46.

The architecture 30 is also flexible to accommodate other wireless communications protocols. For example, a pair of switches 40 and 42 can be provided that are controlled by the DBP 56 to direct the receive and transmit signals through dedicated fixed RF devices 58, such as a global system for mobile communications (GSM) RF front-end module or a WiFi front-end module. In this embodiment, some select signal paths are implemented via conventional RF devices. FIG. 2 only shows one additional signal path, however, this concept can be expanded to any number of additional signal paths depending on use cases and services.

Delta-sigma modulators are a well-known class of devices for implementing analog-to-digital conversion. The fundamental properties that are exploited are oversampling and error feedback (delta) that is accumulated (sigma) to convert the desired signal into a pulse modulated stream that can subsequently be filtered to read off the digital values, while effectively reducing the noise via shaping. The key limitation of known delta-sigma modulators is the quantization noise in the pulse conversion process. Delta-sigma converters require large oversampling ratios in order to produce a sufficient number of bit-stream pulses for a given input. In direct-conversion schemes, the sampling ratio is greater than four times the RF carrier frequency to simplify digital filtering. Thus, required multi-GHz sampling rates have limited the use of delta-sigma modulators in higher frequency applications. Another way to reduce noise has been to use higher order delta-sigma modulators. However, w ile first order canonical delta-sigma architectures are stable, higher orders can be unstable, especially given the tolerances at higher frequencies. For these reasons, state of the art higher order delta-sigma modulators have been limited to audio frequency ranges, i.e., time interleaved delta-sigma modulators, for use in audio applications or specialized interleaving at high frequencies.

The filter characteristics of a Delta-Sigma modulator may effectively be modified in order to compensate for Doppler shift. Doppler shift occurs when the transmitter of a signal is moving in relation to the receiver. The relative movement shifts the frequency of the signal, making it different at the receiver than at the transmitter. An exemplary system according to the present disclosure leverages the software-defined radio architecture to quickly estimate a shift in the carrier frequency and re-center the filter before the signal is disrupted or degraded. In normal operation, the notch of the modulator filter is centered about the expected carrier frequency of the received signal with the signal band information centered around the carrier frequency and not exceeding the bandwidth of the modulator filter. A Doppler shift would offset the carrier by an amount Δf causing potential degradation to signal content with an increase in noise at one side of the band. According to the method and system described herein, the transceiver in a wireless cellular communication system can adapt to changes in the RF carrier frequency and may maintain signal integrity, by shifting the filter notch by the same amount as the carrier frequency.

For the cellular application discussed herein that covers multiple assigned frequency bands, a transmitter with multi-mode and multi-band coverage is required. Also, many current applications mandate transmitters that rapidly switch between frequency bands during the operation of a single communication link, which imposes significant challenges to typical local oscillator (LO) based transmitter solutions. This is because the switching time of the LO-based transmitter is often determined by the LO channel switching time under the control of the loop bandwidth of the frequency synthesizer, around 1 MHz. Hence, the achievable channel switching time is around several microseconds, which unfortunately is too long for an agile radio. A fully digital PWM based multi-standard transmitter, known in the art, suffers from high distortion, and the channel switching time is still determined by the LO at the carrier frequency. A DDS can be used as the LO sourced to enhance the switching speed, however, this design consumes significant power and may not deliver a high frequency LO with low spurious components. Alternately, single sideband mixers can be used to generate a number of LOs with different center frequencies using a common phase-lock loop (PLL), whose channel switching times can be fast. However, this approach can only support a limited number of LO options and any additional channels to cover the wide range of the anticipated 4G bands would need extra mixtures. As discussed, sigma-delta modulators have been proposed in the art to serve as an RF transmitter to overcome these issues. However, in the basic architecture, a sigma-delta modulator cannot provide a very high dynamic range in a wideband of operations due to a moderate clock frequency. It is precisely because the clock frequency is constrained by current technology that this high frequency mode of operations cannot be supported.

Adoption of MIMO (multiple input multiple output) and CA (Carrier Aggregation) techniques for increased mobile data speeds has been constrained by the challenge of designing multiple RF transmission paths in a compact device. Though delta-sigma based transceiver architectures are already more compact than traditional radio architectures, many receivers may still needed for MIMO and CA thus driving the industry to further increase component density. Thus, it would be desirable to implement a low-cost 3D integration method for reducing the receiver footprint to enable an increase in the number of receivers and address existing system limitations.

It would be desirable to have the cellular radio front-end architecture that provides software programmable capabilities utilizing a compact receiver array design to support the demand for increased mobile broadband services. An exemplary system to achieve this capability may be through the use of through-silicon vias (TSVs) to interconnect front-end analog functions in SiGe BiCMOS to backend circuitry in CMOS. This enables SiGe HBT structures and CMOS logic structures to be tightly integrated, making it suitable for mixed-signal circuits. Heterojunction bipolar transistors have higher forward gain and lower reverse gain than traditional homojunction bipolar transistors. This translates into better low current and high frequency performance. Being a heterojunction technology with an adjustable band gap, the SiGe offers the opportunity for more flexible band gap tuning than silicon-only technology whereas CMOS technology offers high input resistance and is excellent for constructing simple, low-power logic gates. This has the desired effect of offering a low-cost, highly-compact solution for increasing the number of receivers needed to meet current communication standards.

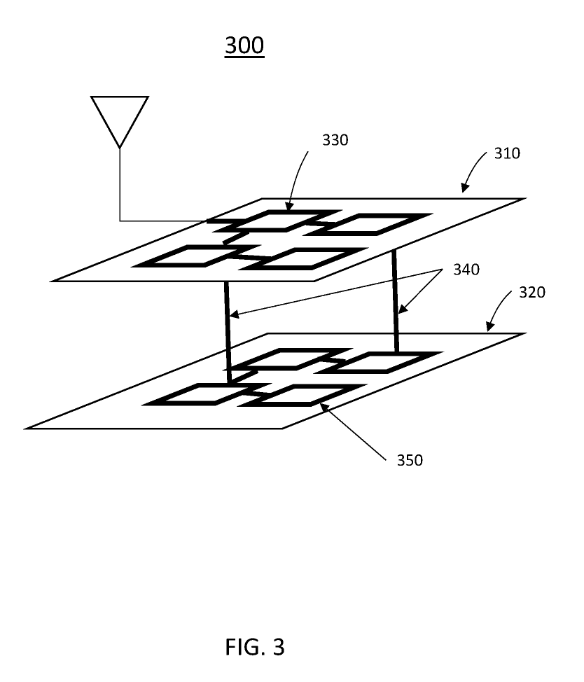

Turning now to FIG. 3, an exemplary radio architecture 300 to implement a delta-sigma modulator in a software defined programmable cellular radio is shown. The radio architecture is implemented in this exemplary embodiment by having a first layer of SiGe 310 and a second layer of silicon 320. The signals are conducted from one layer to the other via TSVs 340. SiGe HBTs are desirable to meet high dynamic range specifications over wideband operation for RF functions 330 such as the front-end low-noise transconductance amplifier (LNTA), modulator filter, and portions of the ADCs and DACs. Digital functions 350 are best implemented in CMOS for lower power operation digital operations. In some systems, the interconnection between the SiGe and CMOS chips is performed using wirebonds or flip-chip technology. However, the inductance from the wirebonds degrades performance at high signal rates and more complex thermal management is needed with flip-chip technology. Improved performance may be achieved by stacking the chips and using the TSVs 340 to create the interconnections.

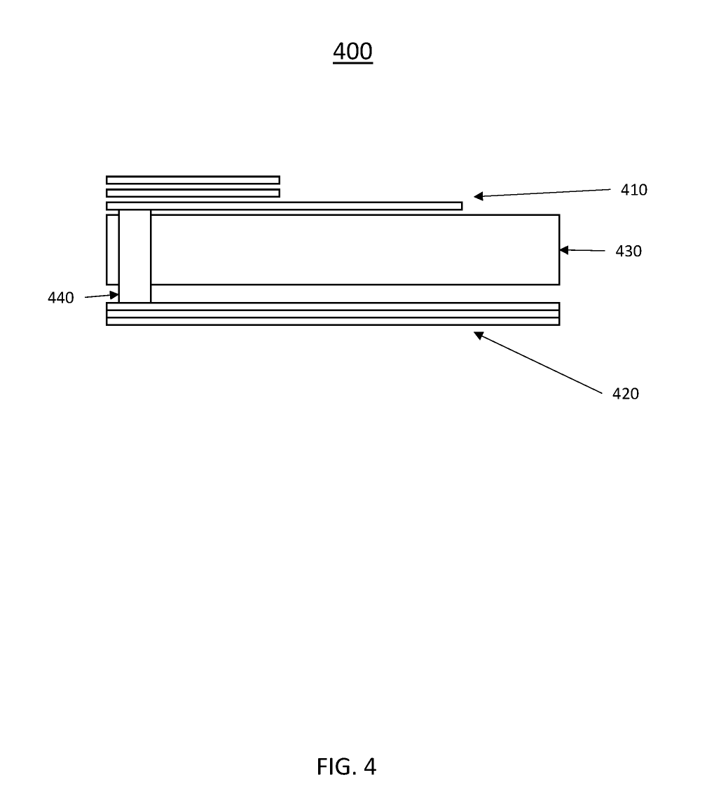

Turning now to FIG. 4, an exemplary cross section of an apparatus 400 having a SiGe BiCMOS and CMOS chip stacks coupled via TSVs is shown. The upper layers depicted are SiGe BiCMOS 410. The lower layers are CMOS 420. The middle layer 430 may be a silicon substrate or the like. The upper layer 410 and lower layer 420 are interconnected via at least one TSV 440. The SiGe BiCMOS with TSV technology facilitates high-volume manufacturing and is used to improve transistor performance. Specifically, SiGe BiCMMOS can improve fitfmax and breakdown voltage in the npn device. A reduction in emitter inductance is of particular benefit to improving the efficiency and PAE of a power amplifier. The back-side plane may be connected using Tungsten-filled via to the M3 layer of the CMOS chip.

A benefit of the proposed system is that no extra IC processing steps are needed for the proposed interconnect. Contact between the two die is made through thermal compression and can be done at sufficiently low temperatures so as not to impact the die. Since there are no constraints on the placement of the TSVs, the die sizes can be optimized and need not be constrained by peripheral I/O. Based on existing known die, the receiver footprint may be reduced by more than 40% using the proposed concept. Furthermore, the TSV interconnects have reduced parasitics as compared to wirebond and flip-chip approaches. The combination of reduced delay and inductive coupling have the desirable effects of improving modulator stability and increasing receiver performance.

As will be well understood by those skilled in the art, the several and various steps and processes discussed herein to describe the invention may be referring to operations performed by a computer, a processor or other electronic calculating device that manipulate and/or transform data using electrical phenomenon. Those computers and electronic devices may employ various volatile and/or non-volatile memories including non-transitory computer-readable medium with an executable program stored thereon including various code or executable instructions able to be performed by the computer or processor, where the memory and/or computer-readable medium may include all forms and types of memory and other computer-readable media.

The foregoing discussion disclosed and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. An apparatus comprising:
a first semiconductor layer formed of silicon germanium;
a second semiconductor layer formed of silicon;
a first device formed on the first semiconductor layer;
a second device formed on the second semiconductor layer; and
a through silicon via coupling the first device and the second device wherein the through silicon via passes through the first semiconductor layer and the second semiconductor layer.

2. The apparatus of claim 1 wherein the second device is a digital signal processor.

3. The apparatus of claim 1 wherein the first device is a delta sigma modulator.

4. The apparatus of claim 3 wherein the first device is coupled to an antenna for receiving a radio frequency signal.

5. The apparatus of claim 1 wherein the first device is an analog device.

6. The apparatus of claim 1 wherein the first semiconductor layer and the second semiconductor layer are formed on a silicon substrate.

7. The apparatus of claim 1 wherein the apparatus is an integrated circuit coupled to an antenna and a vehicle control system.

8. An integrated circuit comprising:
a first semiconductor layer formed of silicon germanium;
a second semiconductor layer formed of silicon;
a first device formed on the first semiconductor layer;
a second device formed on the second semiconductor layer; and
a through silicon via coupling the first device and the second device wherein the trough silicon via passes through the first semiconductor layer and the second semiconductor layer.

9. The integrated circuit of claim 8 wherein the second device is a digital signal processor.

10. The integrated circuit of claim 8 wherein the first device is a delta sigma modulator.

11. The integrated circuit of claim 8 wherein the first device is an analog device.

12. The integrated circuit of claim 8 wherein the second device is coupled to a digital baseband processor;

13. The integrated circuit of claim 8 wherein the first semiconductor layer and the second semiconductor layer are formed on a silicon substrate.

14. The integrated circuit of claim 8 wherein the apparatus is a software controlled radio coupled to an antenna and a vehicle control system.

15. A software programmable radio comprising:
a delta sigma modulator formed on a SiGe layer of an integrated circuit;
a digital signal processor formed on a silicon layer of the integrated circuit;
a through via coupling the delta sigma modulator to the digital signal processor wherein the through via passes through the SiGe layer of the integrated circuit and the silicon layer of the integrated circuit.

16. The software programmable radio of claim 15 wherein the delta sigma modulator is coupled to an antenna and a vehicle control system.

17. The software programmable radio of claim 15 where the SiGe layer and the silicon layer are separated by a silicon substrate.

18. The software programmable radio of claim 15 where the SiGe layer and the silicon layer are formed on either side of a silicon substrate.

19. The software programmable radio of claim 15 wherein the software programmable radio is formed on an integrated circuit.

20. The software programmable radio of claim 15 wherein the software programmable radio receives data related to autonomous vehicle control.
